(19) United States
(12) Patent Application Publication
(10) Pub. No.: US 2006/0158866 A1
(43) Pub. Date: Jul. 20, 2006

(54) Electronic system cabinet having a lower panel with an opening to receive cables

(76) Inventors: Eric C. Peterson, McKinney, TX (US); Christian L. Belady, McKinney, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/039,017

(22) Filed: Jan. 20, 2005

(51) Int. Cl. H05K 5/02

(52) U.S. Cl. 361/796; 361/818; 361/724

(57) ABSTRACT

An electronic system includes a cabinet having an enclosure, with the cabinet having a bottom side and a lower panel spaced apart from the bottom side. Electronic modules are mounted inside the enclosure, where a chamber is defined between the lower panel and the bottom side, and the lower panel has an opening. Cables from the electronic modules extend through the opening in the lower panel into the chamber.

### BACKGROUND

High performance electronic systems, such as computer server systems, storage server systems, telecommunication switch systems, and so forth, typically include a cabinet in which multiple electronic modules (e.g., processing modules, storage modules, switch modules, etc.) can be mounted. The electronic modules are typically removably mounted in the cabinet such that an electronic module can be easily removed for maintenance or upgrade.

In some organizations, the electronic systems can be kept within a room that is specially designed to provide cooling for the electronic systems as well as to provide space for interconnection of the electronic systems with each other and/or to other locations. In many cases, cables from the electronic systems are routed underneath floor tiles in the floor of the room. Cables exit the bottom of each electronic system cabinet, through a cutout in a respective floor tile, and into the space underneath the floor. For ease of removing a floor tile, it is desired that the cutout in the floor tile be at the periphery of the floor tile. Typically, the electronic system whose cables are to be routed through the cutout of the floor tile has to be precisely positioned so that the cables from the electronic system can line up with the cutout in the floor tile. Also, it is often desirable to line up the fronts of respective electronic systems in a room.

Such precise alignment of the electronic system to the respective cutout of the floor tile results from the lack of space underneath the electronic system cabinet. In electronic systems with a large number of electronic modules, there are usually a large number of cables that extend from the electronic modules. Because the bottom side of the electronic system cabinet is relatively close to the floor, there is not much room to manipulate the large number of cables. The inability to manipulate cables that exit the bottom side of the electronic system cabinet means that there is not much flexibility available in positioning the electronic system with respect to a floor tile.

In a room with a relatively large number of electronic systems, the lack of flexibility in positioning electronic systems may lead to inefficient use of the floor area available in the room.

### BRIEF DESCRIPTION OF THE DRAWINGS

FIG. 1 illustrates an electronic system having a cabinet according to an embodiment positioned in a room.

FIG. 2 illustrates an alternative embodiment of the electronic system cabinet.

FIG. 3 illustrates yet another embodiment of a lower panel of the electronic system cabinet.

FIG. 4 is a cross-sectional view of the electronic system cabinet of FIG. 2.

FIG. 5 is a side view of an electronic system including a plurality of electronic modules and cables attached to the electronic modules, which cables extend through an opening in the lower panel of the electronic system cabinet.

FIG. 6 is a top view of a cover used to cover an opening in the lower panel of the electronic system cabinet of FIG. 5, according to an embodiment.

### DETAILED DESCRIPTION

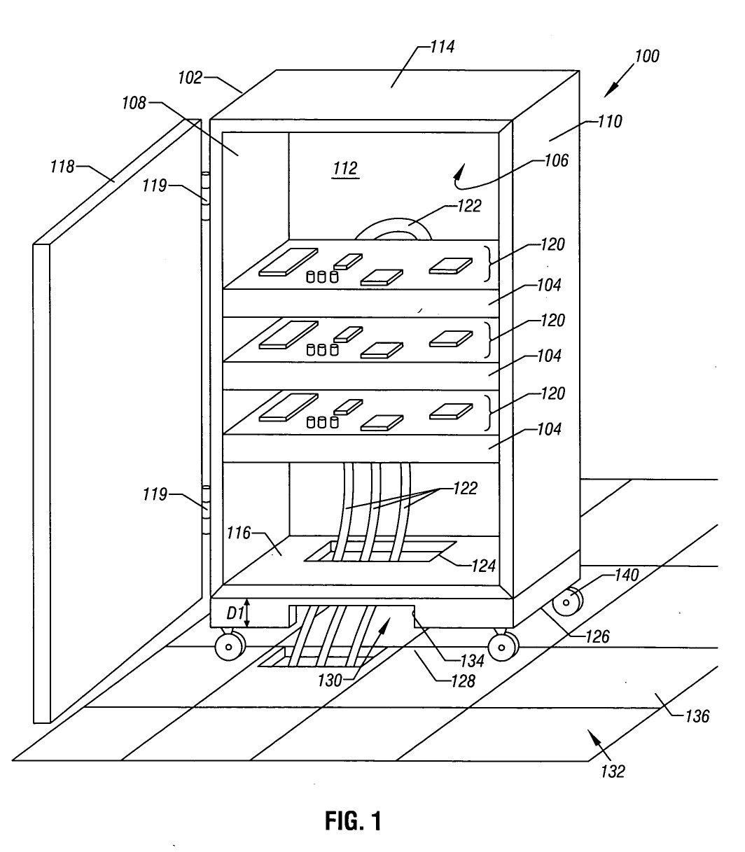

FIG. 1 illustrates an electronic system 100 that has a cabinet 102 for containing multiple electronic modules 104. Examples of the electronic system 100 include computer server systems, storage server systems, telecommunication switch systems, and so forth. Examples of the electronic modules 104 include processor modules, storage modules, switch modules, and so forth.

Each of the electronic modules 104, according to one implementation, is removably mounted in an enclosure 106 defined by the cabinet 102. For example, each electronic module 104 can be slidably mounted such that the electronic module 104 can slide in and out of the enclosure 106. To enable such slidable mounting, sliding profiles can be provided on the sides of electronic modules 104 and corresponding mating profiles can be arranged on the side panels 108 and 110 of the cabinet 102. In alternative implementations, racks can be provided in the cabinet enclosure 106, with the electronic modules 104 placed on such racks. Other mechanisms for mounting the electronic modules 104 in the cabinet 102 can be employed in other implementations.

The enclosure 106 of the cabinet 102 is defined by the side panels 108, 110, a rear panel 112, an upper panel 114, a lower panel 116, and a front door 118. The front door 118 is hingedly attached 119 to the cabinet 102 so that the front door 118 can be opened and closed. Although the enclosure 106 of the cabinet 102 is shaped generally as a polyhedron, and more specifically, a hexahedron, it is contemplated that the enclosure 106 can have other shapes, such as shapes with more curved side and rear panels and upper and lower panels.

Once the front door 118 is shut, the enclosure 106 is covered on all sides. At least portions of each of the side panels 108, 110, rear panel 112, upper and lower panels 114, 116, and front door 118 are formed of an electrically conductive material to provide electromagnetic interference (EMI) shielding when the front door 118 is closed. EMI shielding suppresses electromagnetic emissions from within the enclosure 106 to a location outside the cabinet 102. Electronic emissions are generated by components in each of the electronic modules 104 during high frequency operation of such electronic components. As depicted in FIG. 1, each electronic module 104 has various components 120. In alternative embodiments, instead of using the front door 118, a front panel can be employed instead. The front panel can be attached to the cabinet 102 by some attachment mechanism.

To enable communication among the electronic modules 104, as well as between the electronic modules 104 and devices located remotely from the electronic system 100, one or more cables 122 are connected to each of the electronic modules 104. Each cable 122 includes a bundle of electrical wires, optical fibers, and/or other interconnect structures.

The cables 122 extend from the rear of the electronic modules 104 into a space between the rear of the electronic modules 104 and the rear panel 112 of the cabinet 102. The cables 102 are directed towards the lower portion of the enclosure 106 within the cabinet 102.

In accordance with some embodiments of the invention, an opening 124 is formed in the lower panel 116 of the cabinet 102. The lower panel 116 is raised a distance D1 from the bottom side 126 of the cabinet 102 such that a chamber 130 is defined between the lower panel 116 and the bottom side 126 of the cabinet 102. The “bottom side” of the cabinet 102 refers to the side of the cabinet 102 that is facing the floor. As depicted in FIG. 1, cables 122 are routed through the opening 124 formed in the lower panel 116 into the chamber 130. The chamber 130 defined between the raised lower panel 116 and the bottom side 126 of the cabinet 102 enables an arrangement or positioning of the cables 122 in the chamber 130 such that the cables 122 can be directed toward a cutout 128 formed in a floor tile 136. Provision of the chamber 130 between the lower panel 116 and the bottom side 126 enables the cables 122 to exit the bottom of the cabinet 102 at any location in the footprint of the cabinet 102. Consequently, the electronic system 100 does not have to be precisely aligned with respect to the cutout 128 in the floor tile 136, thereby providing for more flexible positioning of the electronic system 100 on a floor area 132 that is made up of multiple tiles 136. The “footprint” of the cabinet 102 refers to the area projecting from the bottom of the cabinet 102 onto the floor 132.

In some embodiments, a front aperture 134 is provided in a front cabinet portion adjacent the chamber 130. The front of the cabinet 102 is the side of the cabinet 102 where the front door 118 is located. The front aperture 134 enables access by a user of the cables 122 inside the chamber 130. Although not shown, a rear aperture can also be provided at the rear of the cabinet 102 adjacent the chamber 130.

The cables 122 extend through the cutout 128 in the floor tile 136 to enable the cables 122 to be routed underneath the floor tiles 136. The cables from other electronic systems, which can be similarly arranged as electronic system 100, are similarly routed through other corresponding cutouts in floor tiles to enable intercommunication between the electronic systems, as well as with other nodes and user systems.

In the FIG. 1 embodiment, the opening 124 in the lower panel 116 is located towards the rear section of the lower panel 116. The rear section refers to the section of the lower panel 116 closer to the rear panel 112 of the cabinet 102.

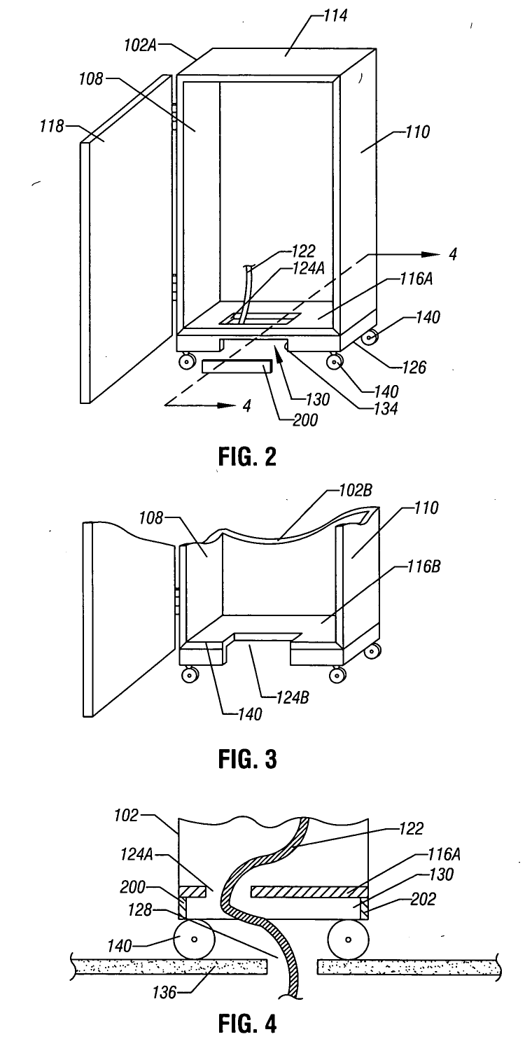

In an alternative embodiment, as depicted in FIG. 2, an alternative cabinet 102A has similarly arranged side panels 108, 110, rear panel 112, upper panel 114, and front door 118. However, a lower panel 116A of the cabinet 102A has an opening 124A that is positioned in a front section of the lower panel 116A (closer to the front door 118). Note that the opening 124 can be located anywhere on the lower panel 116 in other embodiments. Also, in the embodiment of FIG. 2, a cover 200 can be used to cover the front aperture 134 that allows entry into the chamber 130 between the lower panel 116A and bottom side 126 of the cabinet 102. The cover 200 can be used to provide structural support for the cabinet 102 during transportation of the cabinet 102 or to otherwise cover the aperture 134 for aesthetic purposes. A similar cover 202 (FIG. 4) can be provided for a corresponding aperture in the rear side of the cabinet 102.

FIG. 3 depicts yet another embodiment of a cabinet 102B. In this case, instead of forming an opening 124 or 124A that is spaced some distance from the front or rear edge 140 of the lower panel 116B, an opening 124B can be formed adjacent the front edge 140 of the lower panel 116B such that the opening 124B is a cut that is formed in the side of the lower panel 116B. Alternatively, a similar cut can be formed at the rear edge of the lower panel 116B adjacent the rear side of the cabinet.

FIG. 4 is a cross-sectional diagram of a portion of the cabinet 102A of FIG. 2, in which a cable 122 extends through the opening 124A of the lower panel 116A of FIG. 2. The cable 122 extends through the opening 124A into the chamber 130, where it is arranged and positioned in the chamber 130 such that the cable 122 is able to line up with the cutout 128 in the floor tile 136. Note that the bottom side 126 of the cabinet 102 is raised some amount from the floor tile 136 by support structures 140 (FIG. 2) attached to the bottom side of the cabinet 102A. In one implementation, the support structures 140 include wheels or rollers. In other embodiments, other types of support structures 140 can be employed.

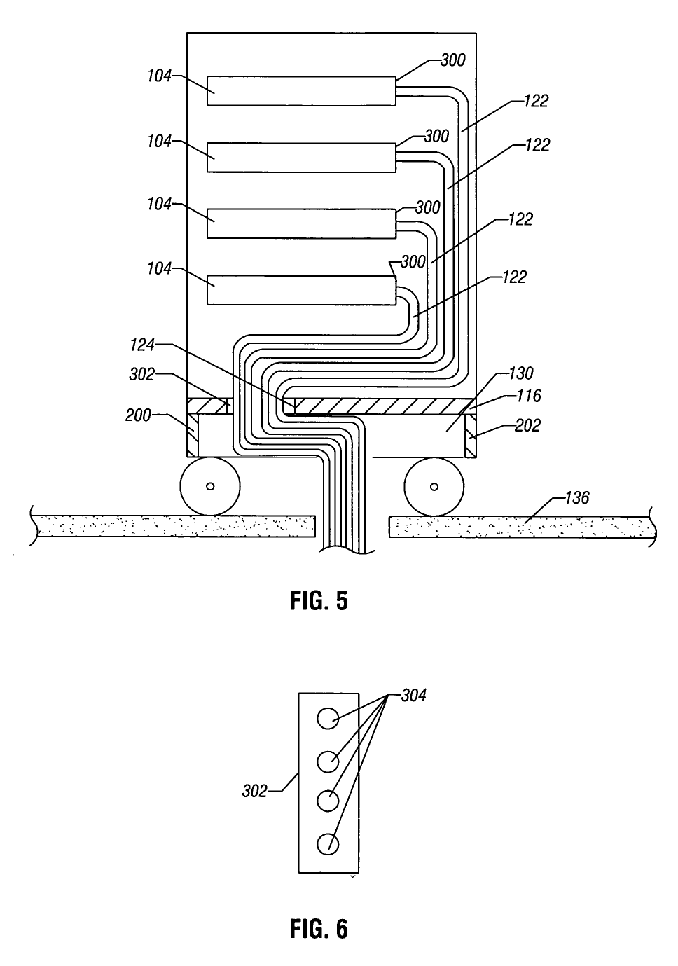

FIG. 5 illustrates a side view of electronic modules 104 mounted in the cabinet 102, with cables 122 from rear sides 300 of respective modules 104. The cables 122 are bundled and routed through the opening 124 in the lower panel 116. Note that the chamber 130 has a height D1 that is defined by the distance between the lower panel 116 and the bottom side 126 (FIG. 1) of the cabinet 102. The height D1 is greater than the combined diameters of at least two cables 122 to enable sufficient space in the chamber 130 to receive and arrange multiple cables 122.

In the embodiments of FIGS. 1-4, the openings 124, 124A, 124B are made as small as possible (while still allowing for the cables 122 to be passed through the opening) to reduce electromagnetic emissions from the enclosure of the cabinet to a location outside the cabinet through the opening.

To further suppress electromagnetic emissions, a cover 302 (shown in FIG. 5) can be used, where the cover 302 is formed of an electrically conductive material that is electrically contacted to the lower panel 116 to provide EMI suppression. A top view of such a cover 302 is provided in FIG. 6, where the cover 302 has apertures 304 through which respective cables 122 can pass.

In a different embodiment, instead of using the cover 302, a deformable EMI gasket can be used instead, where the deformable EMI gasket is provided around the cables 122 to fill in any space in the opening 124 between the cables and the lower panel 116. The EMI gasket, formed of an electrically conductive material to electrically contact the lower panel 116, serves to cooperate with the lower panel 116 to reduce electromagnetic emissions. More generally, the EMI gasket and EMI cover are examples of EMI blocking elements for the opening 124 in the lower panel.

In the foregoing description, numerous details are set forth to provide an understanding of the present invention. However, it will be understood by those skilled in the art that the present invention may be practiced without these details. While the invention has been disclosed with respect to a limited number of embodiments, those skilled in the art will appreciate numerous modifications and variations therefrom. It is intended that the appended claims cover such modifications and variations as fall within the true spirit and scope of the invention.

What is claimed is:

1. An apparatus for mounting electronic modules, comprising:
a cabinet having an enclosure to receive the electronic modules, the cabinet having a bottom side and a lower panel raised a distance above the bottom side; and
a chamber defined between the lower panel and the bottom side, the lower panel having an opening,
wherein the opening is adapted to receive cables extending from the electronic modules to direct the cables into the chamber, and
wherein the chamber enables an arrangement of the cables such that the cables can exit the bottom side of the cabinet at any location in an area corresponding to a footprint of the cabinet.

2. The apparatus of claim 1, further comprising an electromagnetic interference (EMI) blocking element to cover the opening around the cables to reduce electromagnetic emissions from the enclosure.

3. The apparatus of claim 2, wherein the EMI blocking element comprises an EMI cover having apertures to receive corresponding cables.

4. The apparatus of claim 2, wherein the EMI blocking element comprises an EMI gasket to fill in a space around the cables in the opening.

5. The apparatus of claim 1, wherein the cabinet has side panels, a rear panel, an upper panel, and a front panel, wherein the enclosure is defined by the lower panel, side panels, rear panel, upper panel, and front panel.

6. The apparatus of claim 5, wherein the front panel comprises a front door hingedly attached to the cabinet.

7. An electronic system comprising:
a cabinet having an enclosure, the cabinet having a bottom side and a lower panel spaced apart from the bottom side;
electronic modules mounted inside the enclosure, wherein a chamber is defined between the lower panel and the bottom side, and the lower panel has an opening; and
cables connected to the electronic modules, the cables extending from the electronic modules through the opening in the lower panel into the chamber.

8. The electronic system of claim 7, wherein the cables are arrangeable in the chamber to enable the cables to exit the bottom side of the cabinet at any location in an area corresponding to a footprint of the cabinet.

9. The electronic system of claim 8, wherein the enclosure provides an electromagnetic interference (EMI) shield, the opening sized to reduce electromagnetic emissions from the enclosure.

10. The electronic system of claim 7, further comprising an electromagnetic interference (EMI) blocking element for the opening, the EMI blocking element adapted to allow the cables to pass through the opening while suppressing electromagnetic emissions through the opening from the enclosure.

11. The electronic system of claim 10, wherein the EMI blocking element comprises a cover having apertures for corresponding cables, the cover electrically contacted to the lower panel.

12. The electronic system of claim 10, wherein the EMI blocking element comprises a deformable EMI gasket surrounding portions of the cables passing through the opening, the EMI gasket electrically contacted to the lower panel.

13. The electronic system of claim 7, further comprising support structures attached to the bottom side of the cabinet, the support structures to raise the bottom side of the cabinet from a floor.

14. The electronic system of claim 13, wherein the chamber between the lower panel and bottom side of the cabinet provides a volume to enable an arrangement and positioning of the cables in the chamber to route the cables through a cutout in the floor.

15. The electronic system of claim 7, wherein the electronic modules are removably mounted in the enclosure of the cabinet.

16. The electronic system of claim 7, wherein the cabinet further comprises side panels, a rear panel, and an upper panel, wherein the enclosure is defined in part by the upper panel, side panels, rear panel, and lower panel.

17. The electronic system of claim 16, wherein the cabinet further comprises a front door, the enclosure defined by the front door, upper panel, side panels, rear panel, and lower panel.

18. A method for use with an electronic system having a cabinet with an enclosure, comprising:
mounting electronic modules in the enclosure, wherein the enclosure is defined in part by a lower panel that is spaced apart from a bottom side of the cabinet;
providing a chamber between the lower panel and the bottom side of the cabinet;
extending cables from the electronic modules through an opening in the lower panel into the chamber defined between the lower panel and the bottom side of the cabinet; and
arranging the cables within the chamber such that the cables protrude from the bottom of the cabinet at a selected position with respect to a floor on which the cabinet is placed.

19. The method of claim 18, wherein arranging the cables within the chamber comprises arranging the cables such that the cables exit the bottom of the cabinet at any location in an area corresponding to a footprint of the cabinet.

20. The method of claim 18, further comprising providing an electromagnetic interference (EMI) shield with the enclosure.

21. The method of claim 20, wherein providing the EMI shield is accomplished by providing the cabinet with the lower panel, side panels, a rear panel, an upper panel, and a front panel.

22. The method of claim 21, wherein providing the front panel comprises providing a front door that is hingedly attached to the cabinet.

23. The method of claim 18, further comprising covering the opening in the lower panel with an electromagnetic interference (EMI) blocking element around the cables to reduce electromagnetic emissions from the enclosure.

24. The method of claim 23, wherein providing the EMI blocking element comprises providing at least one of an EMI cover and an EMI gasket.

25. An apparatus for mounting electronic modules, comprising:
means for receiving the electronic modules, the means for receiving having a bottom side and a lower panel raised a distance above the bottom side; and
means for providing a chamber defined between the lower panel and the bottom side, the lower panel having an opening,
wherein the opening is for receiving cables extending from the electronic modules to direct the cables into the chamber, and
wherein the chamber enables an arrangement of the cables such that the cables can exit the bottom side of the cabinet at any location in an area corresponding to a footprint of the means for receiving.

26. The apparatus of claim 25, further comprising means for blocking electromagnetic interference (EMI), the means for blocking EMI to cover the opening around the cables to reduce electromagnetic emissions from an enclosure defined by the means for receiving.

27. The apparatus of claim 25, wherein the means for receiving further has side panels, a rear panel, an upper panel, and a front panel, wherein the lower panel, side panels, rear panel, upper panel, and front panel define an enclosure for receiving the electronic modules.
